(19) United States
(12) Patent Application Publication
(10) Pub. No.: US 2012/0320548 A1
(43) Pub. Date: Dec. 20, 2012

(54) FIXING MECHANISM FOR FIXING A BOARD CARD ON A CIRCUIT BOARD AND ELECTRONIC DEVICE THEREWITH

(76) Inventors: Huang-Ping Lu, New Taipei City (TW); Chia-Yuan Hsu, New Taipei City (TW)

(21) Appl. No.: 13/451,569

(22) Filed: Apr. 20, 2012

(30) Foreign Application Priority Data
Jun. 17, 2011 (TW) 100211052

(51) Int. Cl. H05K 7/00

(52) U.S. Cl. 361/760

(57) ABSTRACT

The present invention discloses a fixing mechanism for fixing a board card on a circuit board. The fixing mechanism includes a standoff for supporting the board card on the circuit board. A first end of the standoff is fixed inside a hole on the circuit board. A stepping opening is formed on a second end of the standoff, and the second end of the standoff contacts against the board card. The fixing mechanism further includes a blind rivet, a first end of the blind rivet engages inside the stepping opening, and a second end of the blind rivet fastens on the board card so as to fix the board card on the circuit board.

### BACKGROUND OF THE INVENTION

1. Field of the Invention

The present invention relates to a fixing mechanism for fixing a board card on a circuit board and an electronic device therewith, and more specifically, to a fixing mechanism capable of providing preferred security function and an electronic device therewith.

2. Description of the Prior Art

In general, a trusted platform module for information security can encode and decode data by hardware, and it is often packed on a motherboard, such as inside a south bridge chip for protecting computer information. Furthermore, a board card with the trusted platform module chip can be connected to a connector on the motherboard as a security card. For preventing the board card from being disassembled easily to crack the code, it had better destroy the board card or the circuit on the motherboard as disassembling the board card for preventing the disassembled board card from being cracked. However, it is a pity that the conventional fixing mechanism for fixing the board card can not fill the above-mentioned requirement.

### SUMMARY OF THE INVENTION

The present invention provides a fixing mechanism for fixing a board card on a circuit board and an electronic device therewith, to solve the problems mentioned above.

According to the claimed invention, a fixing mechanism for fixing a board card on a circuit board is disclosed. The fixing mechanism includes a standoff for supporting the board card on the circuit board. A first end of the standoff is fixed inside a hole on the circuit board. A stepping opening is formed on a second end of the standoff, and the second end of the standoff contacts against the board card. The fixing mechanism further includes a blind rivet, a first end of the blind rivet engages inside the stepping opening, and a second end of the blind rivet fastens on the board card so as to fix the board card on the circuit board.

According to the claimed invention, the first end of the standoff is a stepping structure for inserting into the hole on the circuit board.

According to the claimed invention, the first end of the standoff is welded inside the hole on the circuit board.

According to the claimed invention, the second end of the standoff is a non-stepping column structure.

According to the claimed invention, the second end of the standoff contacts a metal ground end on the board card.

According to the claimed invention, the second end of the standoff is a stepping structure for inserting into a slot on the board card.

According to the claimed invention, the standoff is made of metal material.

According to the claimed invention, an electronic device includes a circuit board whereon a hole is formed, a connector installed on the circuit board, a board card connected to the connector and disposed on the circuit board, and a fixing mechanism for fixing the board card on the circuit board. The fixing mechanism includes a standoff for supporting the board card on the circuit board. A first end of the standoff is fixed inside the hole on the circuit board, a second end of the standoff contacts against the board card, and a stepping opening is formed on the second end of the standoff. The fixing mechanism further includes a blind rivet. A first end of the blind rivet engages inside the stepping opening, and a second end of the blind rivet fastens on the board card so as to fix the board card on the circuit board.

The fixing mechanism of the present invention utilizes the combination of the standoff and the blind rivet to fix the board card on the circuit board. It can provide enough structural strength. That is, the standoff and the blind rivet need to be destroyed and the board card can not be disassembled easily as taking off the board card from the circuit board, so as to result in damage to the fixing mechanism, pins of the connector, the board card or the circuit board for preventing the disassembled board card from being cracked to achieve system security.

These and other objectives of the present invention will no doubt become obvious to those of ordinary skill in the art after reading the following detailed description of the embodiment that is illustrated in the various figures and drawings.

### BRIEF DESCRIPTION OF THE DRAWINGS

FIG. 1 and FIG. 2 are respectively an assembly diagram and an exploded diagram of internal components of an electronic device according to an embodiment of the present invention.

FIG. 3 to FIG. 7 are assembly diagrams of the fixing mechanism for fixing the board card according to the embodiment of the present invention.

FIG. 8 is a sectional view of the fixing mechanism for fixing the board card according to the embodiment of the present invention.

FIG. 9 is a diagram of a standoff according to the embodiment of the present invention.

FIG. 10 is a diagram of a board card according to the embodiment of the present invention.

FIG. 11 is a diagram of the fixing mechanism for fixing the board card according to another embodiment of the present invention.

### DETAILED DESCRIPTION

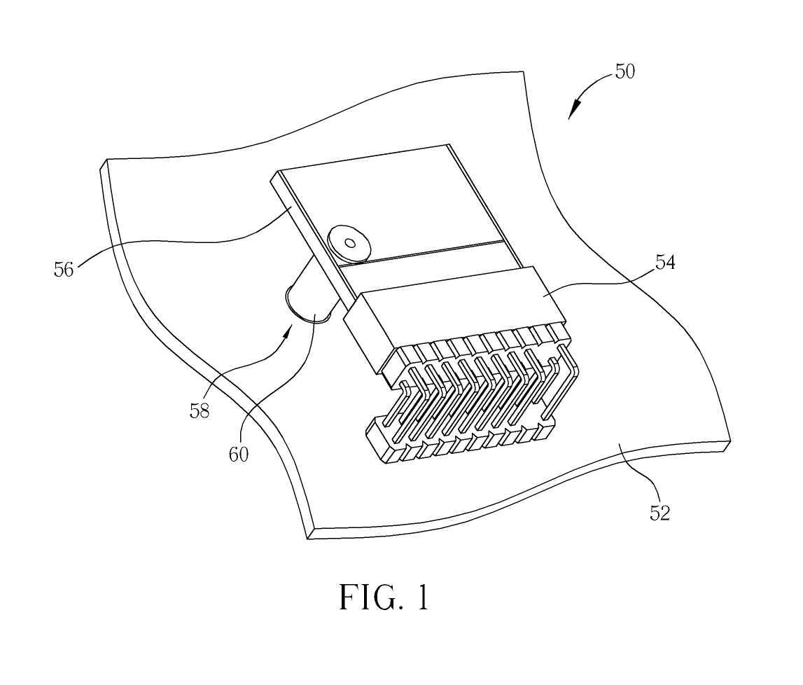

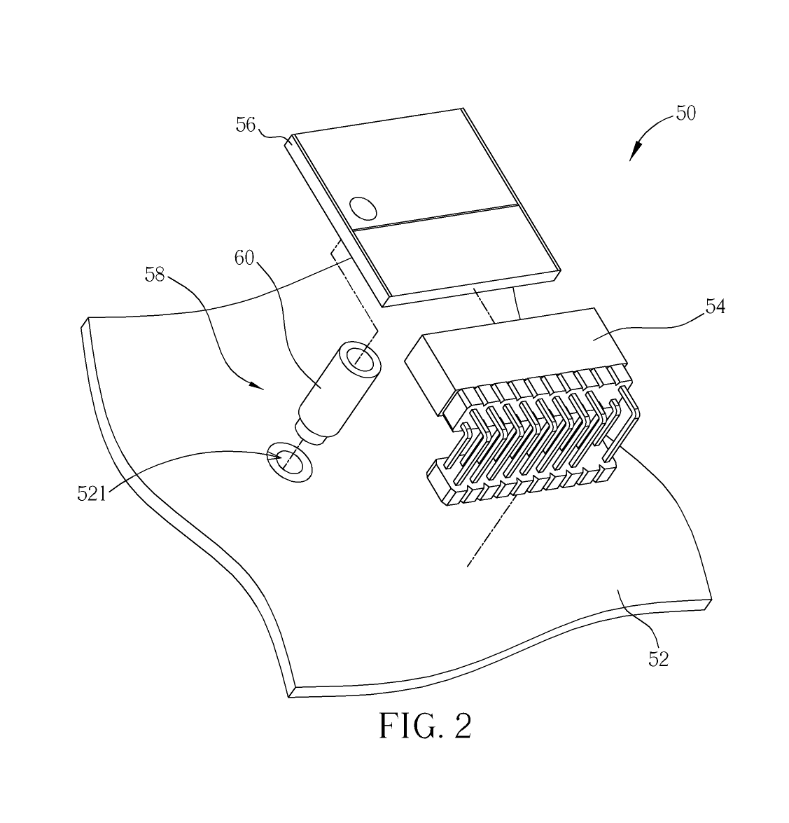

Please refer to FIG. 1 and FIG. 2. FIG. 1 and FIG. 2 are respectively an assembly diagram and an exploded diagram of internal components of an electronic device 50 according to an embodiment of the present invention. The electronic device 50 can be a computer device. The electronic device 50 includes a circuit 52 and a connector 54 installed on the circuit board 52. The connector 54 can be a board to board connector for electrically connecting board cards to the circuit board 52. The electronic device 50 further includes a board card 56. One end of the board card 56 is connected to the connector 54 and disposed on the circuit board 52. The board card 56 can be an external card with a trusted platform module chip for providing security function of the electronic device 50, such as encoding or decoding data for protecting computer information. The electronic device 50 further includes a fixing mechanism 58 for fixing the board card 56 on the circuit board 52. The fixing mechanism 58 includes a standoff 60 for supporting the board card 56 on the circuit board 52. The standoff 60 can be made of metal material. For example, the standoff can be a copper standoff for providing enough structural strength. According, the standoff 60 needs to be destroyed and the board card 56 can not be disassembled easily as taking off the board card 56 from the circuit board 52, so as to resulting in damage to the fixing mechanism 58, pins of the connector 54, the board card 56 or the circuit board 52 for preventing the disassembled board card 56 from being cracked.

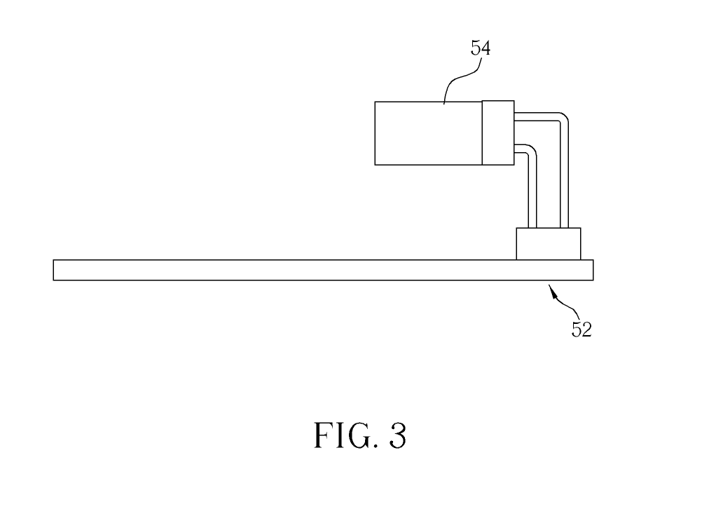

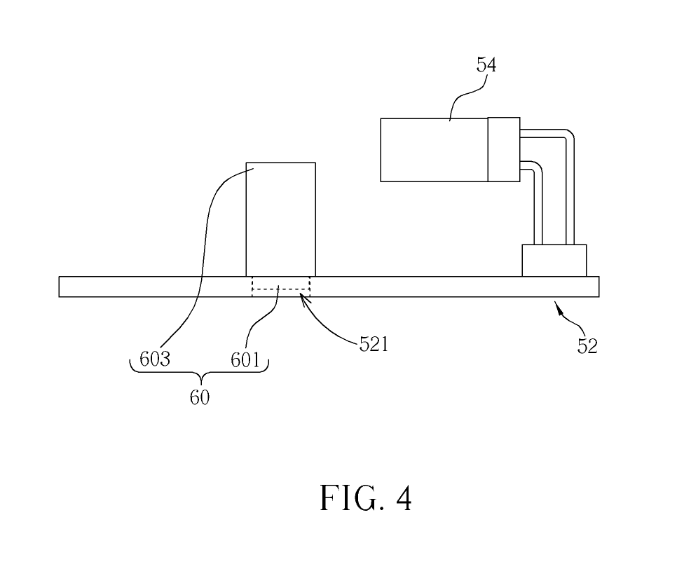

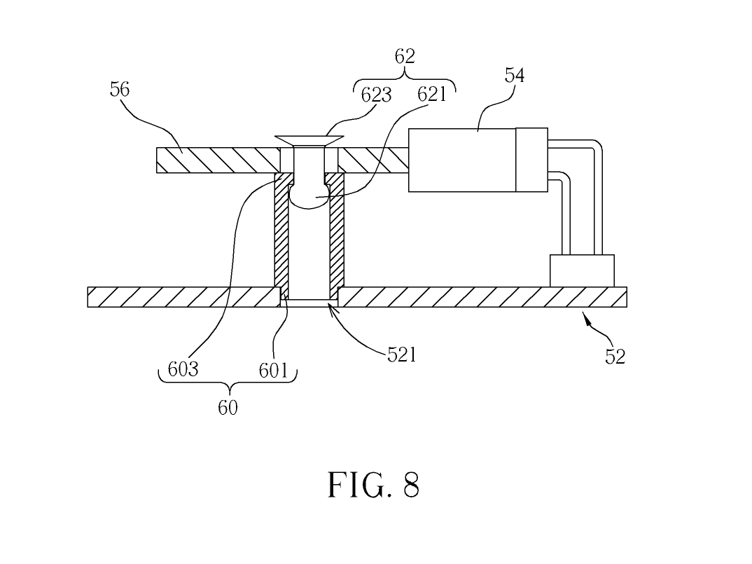

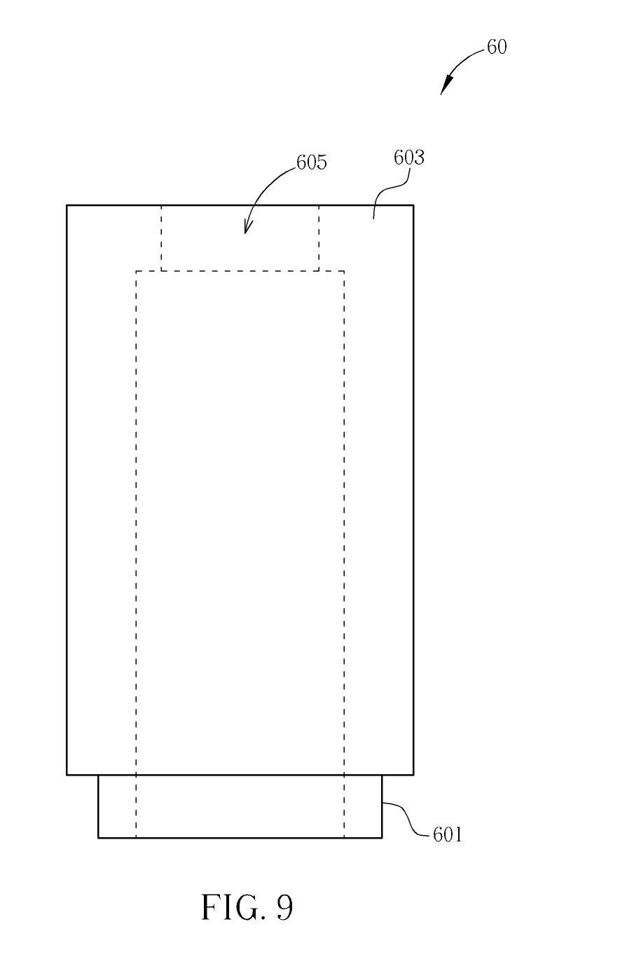

Please refer to FIG. 3 to FIG. 8. FIG. 3 to FIG. 7 are assembly diagrams of the fixing mechanism 58 for fixing the board card 56 according to the embodiment of the present invention. FIG. 8 is a sectional view of the fixing mechanism 58 for fixing the board card 56 according to the embodiment of the present invention. As shown in FIG. 3, the connector 54 is installed on the circuit board 52 first, such as by direct insertion process. As shown in FIG. 4, the standoff 60 is installed on the circuit board 60. Please refer to FIG. 9. FIG. 9 is a diagram of the standoff 60 according to the embodiment of the present invention. A hole 521 is formed on the circuit board 52, and a first end 601 of the standoff 60 is fixed inside the hole 521 on the circuit board 52. For example, the first end 601 of the standoff 60 can be a stepping structure for inserting into the hole 521 on the circuit board 52, and the first end 601 of the standoff 60 can be welded inside the hole 521 on the circuit board 52. That is, the first end 601 of the standoff 60 is inserted into the hole 521 on the circuit board 52, and then the circuit board 52 conveys through a tin stove for welding the first end 601 of the standoff 60 inside the hole 521 on the circuit board 52.

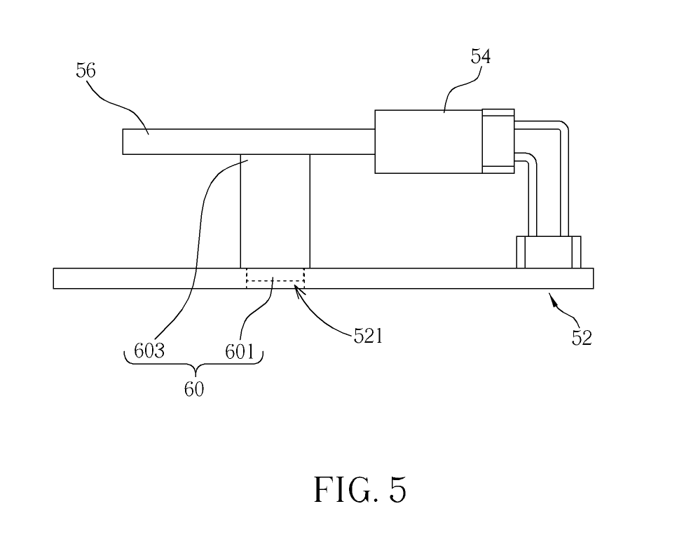

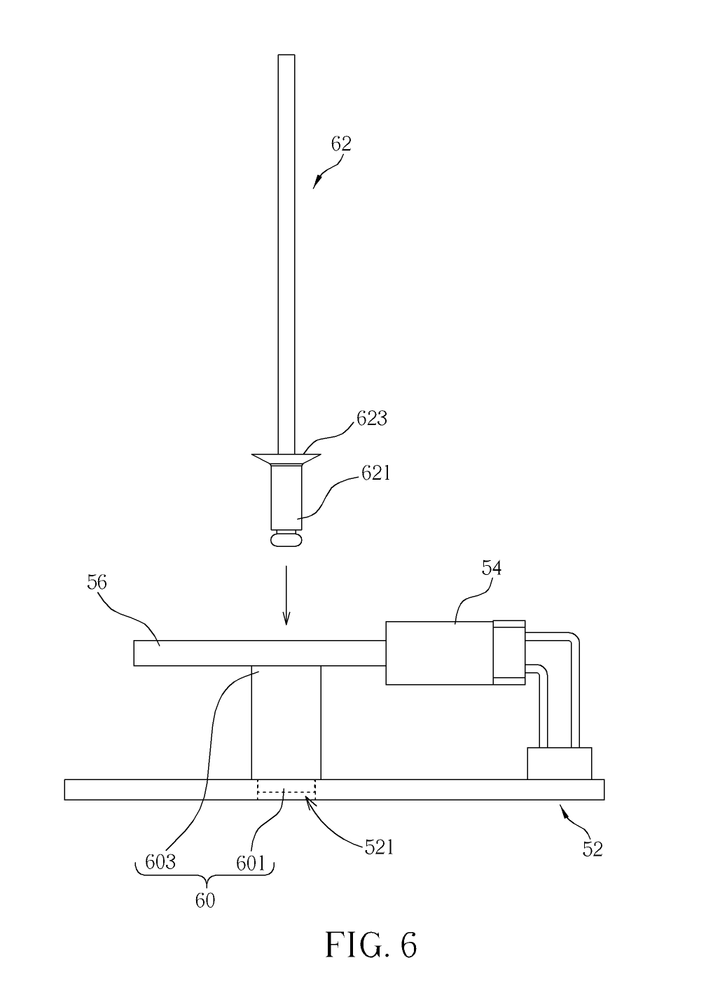

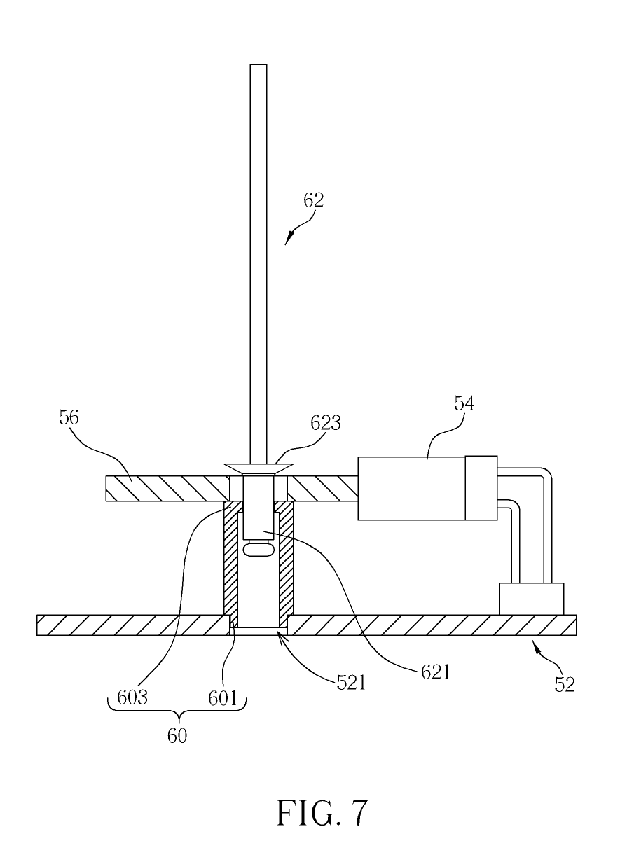

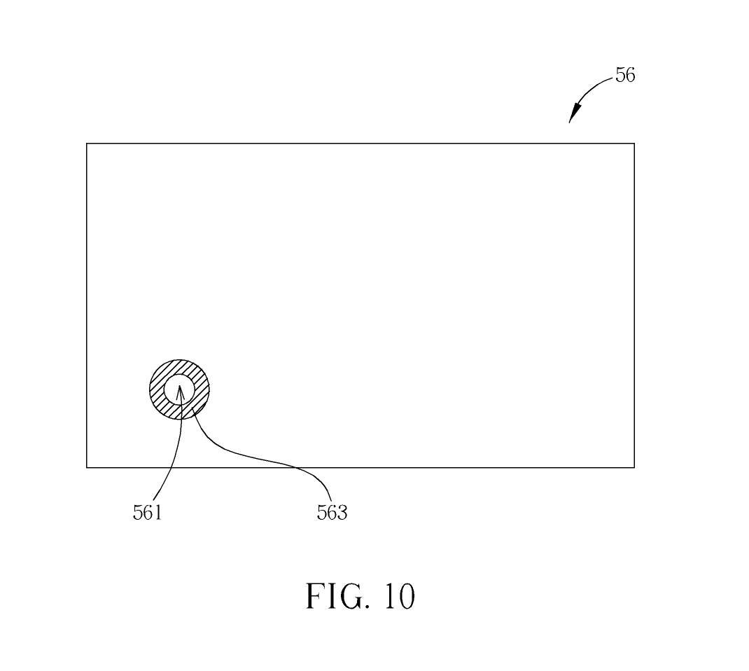

As shown in FIG. 5, the board card 56 is disposed on a second end 603 of the standoff 60 for contacting the second end 603 of the standoff 60 against the board card 56, and an end of the board card 56 is inserted into the connector 54. The second end 603 of the standoff 60 can be a non-stepping column structure. Please refer to FIG. 10. FIG. 10 is a diagram of the board card 56 according to the embodiment of the present invention. An opening 561 is formed on the board card 60, and a metal ground end 563 is disposed around the opening 561. As the second end 603 of the standoff 60 contacts against the board card 56, the second end 603 of the standoff 60 can contact against the metal ground end 563 on the board card 56, so as to ground the board card 56 to the circuit board 52 via the standoff 60 made of metal material. As shown in FIG. 6, the fixing mechanism 58 further includes a blind rivet 62. The blind rivet 62 can pass through the opening 561 on the board card 56 to insert into the standoff 60. As shown in FIG. 7 and FIG. 8, the blind rivet 62 can be drawn upward and distant from the standoff 60 and then the rod of the blind rivet 62 can be cut down. A stepping opening 605 is formed on the second end 603 of the standoff 60, a first end 621 of the blind rivet 62 can be engaged inside the stepping opening 605 of the standoff 60, and a second end 603 of the blind rivet 62 can be fastened on the board card 56 so as to fix the board card 56 on the circuit board 52 firmly.

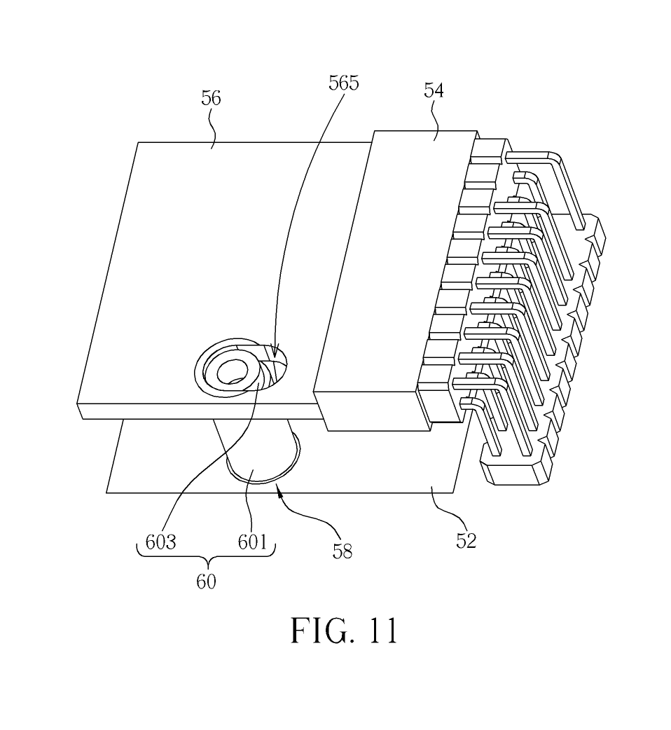

Please refer to FIG. 11. FIG. 11 is a diagram of the fixing mechanism 58 for fixing the board card 56 according to another embodiment of the present invention. The difference between the above-mentioned embodiment and this embodiment is that a slot 565 is formed on the board card 56 instead of the opening 561, and the second end 603 of the standoff 60 is a stepping structure for inserting into the slot 565 on the board card 56 obliquely, so that a bottom of the board card 56 can not be damaged as assembling the board card 56. The combination of the slot 565 on the board card 56 and the stepping structure of the standoff 60 can be selectively arranged, and it depends on actual design. For simplicity, elements that have the same functions as that illustrated in the above-mentioned embodiment are provided with the same item numbers, and a further description is hereby omitted.

In contrast to the prior art, the fixing mechanism of the present invention utilizes the combination of the standoff and the blind rivet to fix the board card on the circuit board. It can provide enough structural strength. That is, the standoff and the blind rivet need to be destroyed and the board card can not be disassembled easily as taking off the board card from the circuit board, so as to result in damage to the fixing mechanism, pins of the connector, the board card or the circuit board for preventing the disassembled board card from being cracked to achieve system security.

Those skilled in the art will readily observe that numerous modifications and alterations of the device and method may be made while retaining the teachings of the invention.

What is claimed is:

1. A fixing mechanism for fixing a board card on a circuit board, comprising:
a standoff for supporting the board card on the circuit board, a first end of the standoff being fixed inside a hole on the circuit board, a second end of the standoff contacting against the board card, and a stepping opening being formed on the second end of the standoff; and
a blind rivet, a first end of the blind rivet engaging inside the stepping opening, and a second end of the blind rivet fastening on the board card so as to fix the board card on the circuit board.

2. The fixing mechanism of claim 1, wherein the first end of the standoff is a stepping structure for inserting into the hole on the circuit board.

3. The fixing mechanism of claim 2, wherein the first end of the standoff is welded inside the hole on the circuit board.

4. The fixing mechanism of claim 1, wherein the second end of the standoff is a non-stepping column structure.

5. The fixing mechanism of claim 4, wherein the second end of the standoff contacts a metal ground end on the board card.

6. The fixing mechanism of claim 1, wherein the second end of the standoff is a stepping structure for inserting into a slot on the board card.

7. The fixing mechanism of claim 1, wherein the standoff is made of metal material.

8. An electronic device comprising:
a circuit board whereon a hole is formed;
a connector installed on the circuit board;
a board card connected to the connector and disposed on the circuit board; and
a fixing mechanism for fixing the board card on the circuit board, comprising:
a standoff for supporting the board card on the circuit board, a first end of the standoff being fixed inside the hole on the circuit board, a second end of the standoff contacting against the board card, and a stepping opening being formed on the second end of the standoff; and
a blind rivet, a first end of the blind rivet engaging inside the stepping opening, and a second end of the blind rivet fastening on the board card so as to fix the board card on the circuit board.

9. The electronic device of claim 8, wherein the first end of the standoff is a stepping structure for inserting into the hole on the circuit board.

10. The electronic device of claim 9, wherein the first end of the standoff is welded inside the hole on the circuit board.

11. The electronic device of claim 8, wherein the second end of the standoff is a non-stepping column structure.

12. The electronic device of claim 11, wherein a metal ground end is formed on the board card, and the second end of the standoff contacts the metal ground end on the board card.

13. The electronic device of claim 8, wherein a slot is formed on the board card, and the second end of the standoff is a stepping structure for inserting into the slot on the board card.

14. The electronic device of claim 8, wherein the standoff is made of metal material.
